(19) United States
(12) Patent Application Publication
(10) Pub. No.: US 2026/0246440 A1
(43) Pub. Date: Aug. 20, 2026

(54) HYBRID NOISE FILTER

(71) Applicant: ASIAN POWER DEVICES INC., Taoyuan City (TW)

(72) Inventor: Tsung-Liang HUNG, Taoyuan City (TW)

(73) Assignee: ASIAN POWER DEVICES INC., Taoyuan City (TW)

(21) Appl. No.: 19/183,356

(22) Filed: Apr. 18, 2025

(30) Foreign Application Priority Data
Feb. 20, 2025 (TW) 114106320

(51) Int. Cl. H03H 7/01

(52) U.S. Cl. CPC H03H 7/0115

(57) ABSTRACT

A hybrid noise filter includes a differential-mode filter unit and a common-mode filter unit. The differential-mode filter unit includes a differential-mode input side and a differential-mode output side, and the differential-mode input side is connected to the input power source. The differential-mode filter unit includes a differential-mode inductor and a differential-mode capacitor. The differential-mode capacitor is connected to a second winding of the differential-mode inductor in series. The common-mode filter unit includes a common-mode input side and a common-mode output side, and the common-mode input side is connected to the differential-mode output side and the common-mode output side is connected to the power converter. The common-mode filter unit includes a common-mode inductor and a first common-mode capacitor. The first common-mode capacitor is connected to a third winding of the common-mode inductor in series and to a ground terminal.

### CROSS-REFERENCE TO RELATED APPLICATION

This application claims benefit of priority to Taiwanese Patent Application No. 114106320 filed Feb. 20, 2025, the entire contents of which are incorporated herein by reference.

### BACKGROUND

### Technical Field

The present disclosure relates to a noise filter, and more particularly to a hybrid noise filter.

### Description of Related Art

The statements in this section merely provide background information related to the present disclosure and do not necessarily constitute prior art.

In the structure of the related-art switching power converter, there is typically a common-mode noise filter at its input terminal, consisting of a common-mode inductor and Y capacitors (including a capacitor C₁ and a capacitor C₂). This common-mode noise filter usually has one to three sets. Due to the frequency range of conduction electromagnetic interference (EMI) ranging from 150 kHz to 30 MHz, and the fact that filters typically have limited response bandwidth, multiple sets of filters are required.

The performance of a filter is directly related to the attenuation performance within the bandwidth. In order to achieve better noise attenuation, traditional methods use common-mode inductors with two windings N₁, N₂, which require higher inductance, and therefore they have larger size and higher cost. Moreover, a high-inductance inductor typically requires a greater number of wire windings, resulting in increased efficiency losses and heat generation. Please refer to FIG. 1, which shows a circuit diagram of a conventional switching power converter. From FIG. 1, it is evident that the common-mode current i_{cm} typically flows through the secondary side and is transmitted to the ground FG, and then returns to a line impedance stabilization network (LISN) via the ground FG. Subsequently, the common-mode current i_{cm} is detected by the EMI receiver.

Therefore, how to design a noise filter, and particularly to a hybrid noise filter to solve the problems and technical bottlenecks in the existing technology has become a critical topic in this field.

### SUMMARY

An objective of the present disclosure is to provide a hybrid noise filter. The hybrid noise filter is coupled between an input power source and a power converter. The hybrid noise filter includes a differential-mode filter unit and a common-mode filter unit. The differential-mode filter unit includes a differential-mode inductor and a differential-mode capacitor. The differential-mode inductor includes a first winding and a second winding. The differential-mode capacitor is connected to the second winding of the differential-mode inductor in series. The common-mode filter unit includes a common-mode input side and a common-mode output side, and the common-mode input side is connected to the differential-mode output side and the common-mode output side is connected to the power converter. The common-mode filter unit includes a common-mode inductor and a first common-mode capacitor. The common-mode inductor includes a first winding, a second winding, and a third winding. Th first common-mode capacitor is connected to the third winding of the common-mode inductor and connected to a ground terminal.

In one embodiment, the first winding of the differential-mode inductor includes a first terminal and a second terminal, the second winding of the differential-mode inductor includes a first terminal and a second terminal, and the differential-mode capacitor includes a first terminal and a second terminal. The first terminal of the first winding is connected to the first terminal of the second winding, and the second terminal of the second winding is connected to the first terminal of the differential-mode capacitor. The first terminal of the first winding and the second terminal of the differential-mode capacitor form the differential-mode input side. The second terminal of the first winding and the second terminal of the differential-mode capacitor form the differential-mode output side.

In one embodiment, a polarity of the second terminal of the first winding of the differential-mode inductor is the same as a polarity of the second terminal of the second winding of the differential-mode inductor.

In one embodiment, the first winding of the common-mode inductor includes a first terminal and a second terminal, the second winding of the common-mode inductor includes a first terminal and a second terminal, the third winding of the common-mode inductor includes a first terminal and a second terminal, and the first common-mode capacitor includes a first terminal and a second terminal. The first terminal of the first winding is connected to the first terminal of the third winding, and the second terminal of the third winding is connected to the first terminal of the first common-mode capacitor. The first terminal of the first winding and the first terminal of the second winding form the common-mode input side. The second terminal of the first winding and the second terminal of the second winding form the common-mode output side.

In one embodiment, a polarity of the second terminal of the first winding of the common-mode inductor is the same as a polarity of the second terminal of the second winding of the common-mode inductor, and a polarity of the second terminal of the second winding of the common-mode inductor is the same as a polarity of the second terminal of the third winding of the common-mode inductor.

In one embodiment, the common-mode filter unit further includes a second common-mode capacitor. The second common-mode capacitor is connected between the common-mode input side.

In one embodiment, the common-mode filter unit further includes a second common-mode capacitor. The second common-mode capacitor includes a first terminal and a second terminal. The first terminal of the second common-mode capacitor is connected to the first terminal of the third winding, and the second terminal of the second common-mode capacitor is connected to the first terminal of the second winding.

Another objective of the present disclosure is to provide a hybrid noise filter. The hybrid noise filter is coupled between an input power source and a power converter. The hybrid noise filter includes a common-mode filter unit and a differential-mode filter unit. The common-mode filter unit includes a common-mode input side and a common-mode output side, and the common-mode input side is connected to the input power source. The common-mode filter unit includes a common-mode inductor and a first common-mode capacitor. The common-mode inductor includes a first winding, a second winding, and a third winding. The first common-mode capacitor is connected to the third winding of the common-mode inductor in series and connected to a ground terminal. The differential-mode filter unit includes a differential-mode input side and a differential-mode output side, and the differential-mode input side is connected to the common-mode output side and the differential-mode output side is connected to the power converter. The differential-mode filter unit includes a differential-mode inductor and a differential-mode capacitor. The differential-mode inductor includes a first winding and a second winding. The differential-mode capacitor is connected to the second winding of the differential-mode inductor.

In one embodiment, the first winding of the common-mode inductor includes a first terminal and a second terminal, the second winding of the common-mode inductor includes a first terminal and a second terminal, and the first common-mode capacitor includes a first terminal and a second terminal. The first terminal of the first winding is connected to the first terminal of the third winding, and the second terminal of the third winding is connected to the first terminal of the first common-mode capacitor. The first terminal of the first winding and the first terminal of the second winding form the common-mode input side. The second terminal of the first winding and the second terminal of the second winding form the common-mode output side.

In one embodiment, a polarity of the second terminal of the first winding of the common-mode inductor is the same as a polarity of the second terminal of the second winding of the common-mode inductor, and a polarity of the second terminal of the second winding of the common-mode inductor is the same as a polarity of the second terminal of the third winding of the common-mode inductor.

In one embodiment, the first winding of the differential-mode inductor includes a first terminal and a second terminal, the second winding of the differential-mode inductor includes a first terminal and a second terminal, and the differential-mode capacitor includes a first terminal and a second terminal. The first terminal of the first winding is connected to the first terminal of the second winding, and the second terminal of the second winding is connected to the first terminal of the differential-mode capacitor. The first terminal of the first winding and the second terminal of the differential-mode capacitor form the differential-mode input side. The second terminal of the first winding and the second terminal of the differential-mode capacitor form the differential-mode output side.

In one embodiment, a polarity of the second terminal of the first winding of the differential-mode inductor is the same as a polarity of the second terminal of the second winding of the differential-mode inductor.

In one embodiment, the common-mode filter unit further includes a second common-mode capacitor. The second common-mode capacitor is connected between the common-mode input side.

In one embodiment, the common-mode filter unit further includes a second common-mode capacitor. The second common-mode capacitor includes a first terminal and a second terminal. The first terminal of the second common-mode capacitor is connected to the first terminal of the third winding, and the second terminal of the second common-mode capacitor is connected to the first terminal of the second winding.

Accordingly, the hybrid noise filter proposed in the present disclosure can achieve advantages of cancelling differential-mode noise currents and common-mode noise currents.

It is to be understood that both the foregoing general description and the following detailed description are exemplary, and are intended to provide further explanation of the present disclosure as claimed. Other advantages and features of the present disclosure will be apparent from the following description, drawings, and claims.

### BRIEF DESCRIPTION OF DRAWINGS

The present disclosure can be more fully understood by reading the following detailed description of the embodiment, with reference made to the accompanying drawing as follows:

FIG. 1 is a circuit diagram of a conventional switching power converter.

FIG. 2 is a circuit diagram of a hybrid noise filter according to a first embodiment of the present disclosure.

FIG. 3 is a schematic diagram showing currents labeled in FIG. 2.

FIG. 4 is a schematic diagram of differential-mode noise currents processed in FIG. 2.

FIG. 5 is a schematic diagram of common-mode noise currents processed in FIG. 2.

FIG. 6 is a circuit diagram of the hybrid noise filter according to a second embodiment of the present disclosure.

FIG. 7 is a circuit diagram of the hybrid noise filter according to a third embodiment of the present disclosure.

FIG. 8 is a circuit diagram of the hybrid noise filter according to a fourth embodiment of the present disclosure.

### DETAILED DESCRIPTION

Reference will now be made to the drawing figures to describe the present disclosure in detail. It will be understood that the drawing figures and exemplified embodiments of present disclosure are not limited to the details thereof.

The implementation of the present disclosure is described below through specific examples, and those who are familiar with this technology can easily understand other advantages and effects of the present disclosure from the content disclosed in this specification. The present disclosure can also be implemented or applied through other different specific examples, and the details in the present disclosure can also be modified and changed based on different viewpoints and applications without departing from the spirit of the present disclosure.

The structures, proportions, sizes, and number of components shown in the drawings attached to the present disclosure are only used to match the content in the present disclosure, for those who are familiar with this technology to understand and read, and are not used to limit the implementation of the present disclosure. Any modification of structure, change of proportional relationship or adjustment of size shall fall within the scope covered by the technical content disclosed in the present disclosure, provided that it does not affect the effect and purpose of the present disclosure.

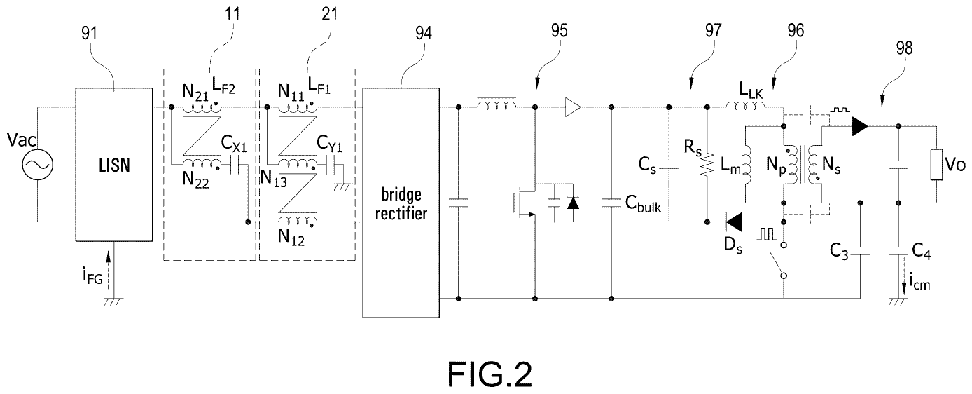

Please refer to FIG. 2, which shows a circuit diagram of a hybrid noise filter according to a first embodiment of the present disclosure. The hybrid noise filter is coupled between an input power source Vac and a power converter. Incidentally, the power converter includes all of or part of a bridge rectifier 94, a voltage conversion circuit 95, a transformer 96, a protection circuit 97, and an output rectifier 98, but the present disclosure is not limited thereto.

As shown in FIG. 2, the hybrid noise filter includes a differential-mode filter unit 11 and a common-mode filter unit 21. The differential-mode filter unit 11 includes a differential-mode input side (i.e., an input side of the differential-mode filter unit 11) and a differential-mode output side (i.e., an output side of the differential-mode filter unit 11). In particular, the differential-mode input side is connected to the input power source Vac, and more specifically, is connected to the input power source Vac through a line impedance stabilization network (LISN) 91. The differential-mode filter unit 11 includes a differential-mode inductor L_{F2} and a differential-mode capacitor C_{X1}. The differential-mode inductor L_{F2} includes a first winding N₂₁ and a second winding N₂₂. The differential-mode capacitor C_{X1} is connected to the second winding N₂₂ in series.

The common-mode filter unit 21 includes a common-mode input side (i.e., an input side of the common-mode filter unit 21) and a common-mode output side (i.e., an output side of the common-mode filter unit 21), and the common-mode input side is connected to the differential-mode output side and the common-mode output side is connected to the power converter. The common-mode filter unit 21 includes a common-mode inductor L_{F1} and a first common-mode capacitor C_{Y1}. The common-mode inductor L_{F1} includes a first winding N₁₁, a second winding N ₁₂, and a third winding N₁₃. The first common-mode capacitor C_{Y1} is connected to the third winding N₁₃ of the common-mode inductor L_{F1} and connected to a ground terminal.

As shown in FIG. 2, specifically, the first winding N₂₁ of the differential-mode inductor L_{F2} includes a first terminal and a second terminal, the second winding N₂₂ of the differential-mode inductor L_{F2} includes a first terminal and a second terminal, and the differential-mode capacitor C_{X1} includes a first terminal and a second terminal. In particular, the first terminal of the first winding N₂₁ is connected to the first terminal of the second winding N₂₂, and the second terminal of the second winding N₂₂ is connected to the first terminal of the differential-mode capacitor C_{X1}. In particular, the first terminal of the first winding N₂₁ and the second terminal of the differential-mode capacitor C_{X1} form the differential-mode input side. In particular, the second terminal of the first winding N₂₁ and the second terminal of the differential-mode capacitor C_{X1} form the differential-mode output side.

Furthermore, a polarity of the second terminal of the first winding N₂₁ of the differential-mode inductor L_{F2} is the same as a polarity of the second terminal of the second winding N₂₂ of the differential-mode inductor L_{F2}. For example, in this embodiment, the second terminal of the first winding N₂₁ and the second terminal of the second winding N₂₂ are both dotted polarities; on the contrary, the first termina of the first winding N₂₁ and the first terminal of the second winding N₂₂ are both non-dotted polarities.

As shown in FIG. 2, specifically, the first winding N₁₁ of the common-mode inductor L_{F1} includes a first terminal and a second terminal, the second winding N₁₂ of the common-mode inductor L_{F1} includes a first terminal and a second terminal, the third winding N₁₃ of the common-mode inductor L_{F1} includes a first terminal and a second terminal, and the first common-mode capacitor C_{Y1} includes a first terminal and a second terminal. In particular, the first terminal of the first winding N₁₁ is connected to the first terminal of the third winding N₁₃, and the second terminal of the third winding N₁₃ is connected to the first terminal of the first common-mode capacitor C_{Y1}. In particular, the first terminal of the first winding N₁₁ and the first terminal of the second winding N₁₂ form the common-mode input side. In particular, the second terminal of the first winding N₁₁ and the second terminal of the second winding N₁₂ form the common-mode output side.

Furthermore, a polarity of the second terminal of the first winding N₁₁ of the common-mode inductor L_{F1} is the same as a polarity of the second terminal of the second winding N₁₂ of the common-mode inductor L_{F1}, and a polarity of the second terminal of the second winding N₁₂ of t he common-mode inductor L_{F1} is the same as a polarity of the second terminal of the third winding N₁₃ of the common-mode inductor L_{F1}. For example, in this embodiment, the second terminal of the first winding N₁₁, the second terminal of the second winding N₁₂, and a second terminal of the third winding N₁₃ are all dotted polarities; on the contrary, the first terminal of the first winding N₁₁, the first terminal of the second winding N₁₂, and a first terminal of the third winding N₁₃ are all non-dotted polarities.

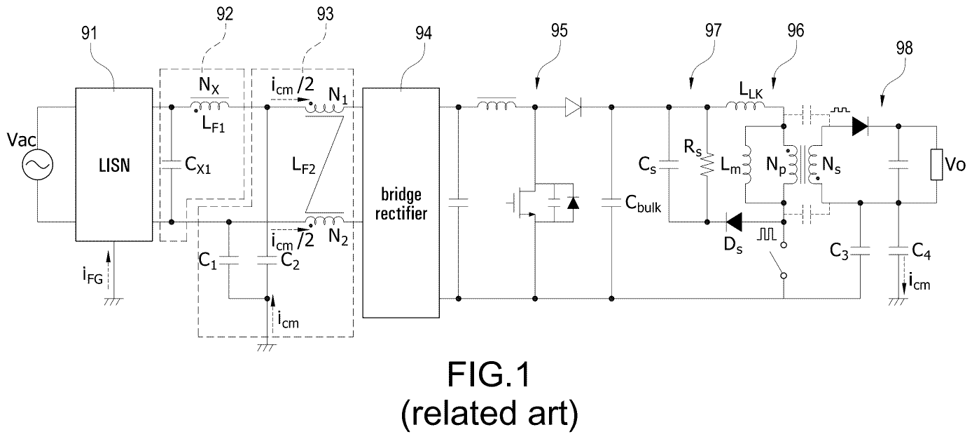

In the circuit of the first embodiment shown in FIG. 2, compared with the conventional circuit of FIG. 1, only two magnetic components L_{F1}, L_{F2} (i.e., the common-mode inductor L_{F1} and the differential-mode inductor L_{F2}) are needed. The common-mode inductor L_{F1} may use a high-permeability iron core to reduce the number of winding turns, while the differential-mode inductor L_{F2} may use a low-permeability iron core to reduce its maximum magnetic flux density. The number of coil turns of the common-mode inductor L_{F1} and the number of coil turns of the differential-mode inductor L_{F2} may be the same, that is, the number of coil turns of the first winding N₁₁ is the same as the number of coil turns of the second winding N₁₂ and the number of coil turns of the third winding N₁₃. Therefore, the hybrid noise filter of the first embodiment is based on the current cancellation technology and can achieve a more efficient noise cancellation.

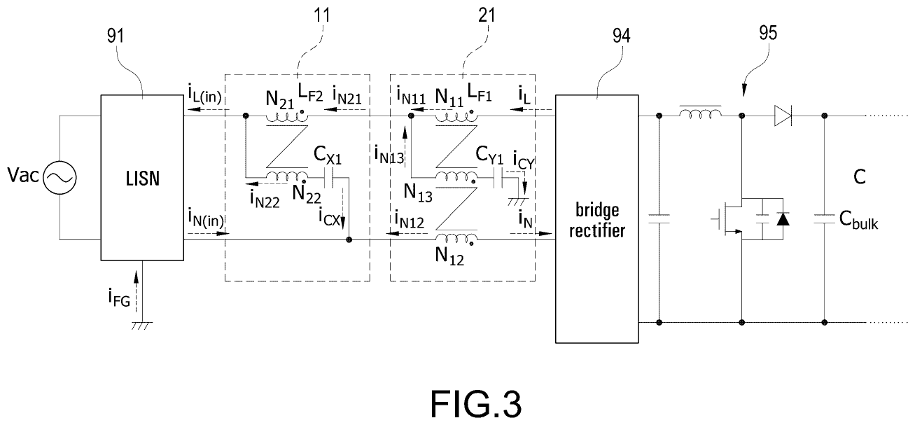

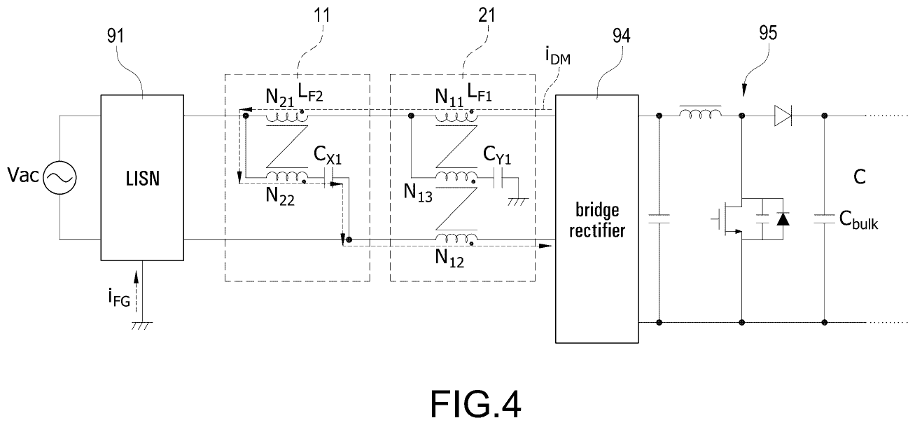

In the circuit of the first embodiment shown in FIG. 3, the current signs of various points have been defined. Furthermore, in the circuit of the first embodiment shown in FIG. 4, the circuit processing of the differential-mode noise current i_{DM} is demonstrated. It can be clearly seen from FIG. 4 that when the differential-mode noise current i_{DM} enters the winding of the common-mode inductor L_{F1}, the magnetic field lines generated by the first winding N₁₁ and the second winding N₁₂ will cancel each other out, resulting in the common-mode inductor L_{F1} having no effect on the differential-mode noise current i_{DM}. Therefore, the differential-mode noise current i_{DM} will completely pass through the common-mode inductor L_{F1} and then enter the differential-mode inductor L_{F2}, and generate currents of the same magnitude but opposite directions in the first winding N₂₁ and the second winding N₂₂. The first winding N₂₁ and the second winding N₂₂ are connected to the differential-mode capacitor C_{X1} in series, and therefore it can be observed that the differential-mode noise current i_{DM} flows back to the noise source after being emitted from the noise source on the right side. Therefore, the LISN 91 in FIG. 4 will not detect the differential-mode noise currents.

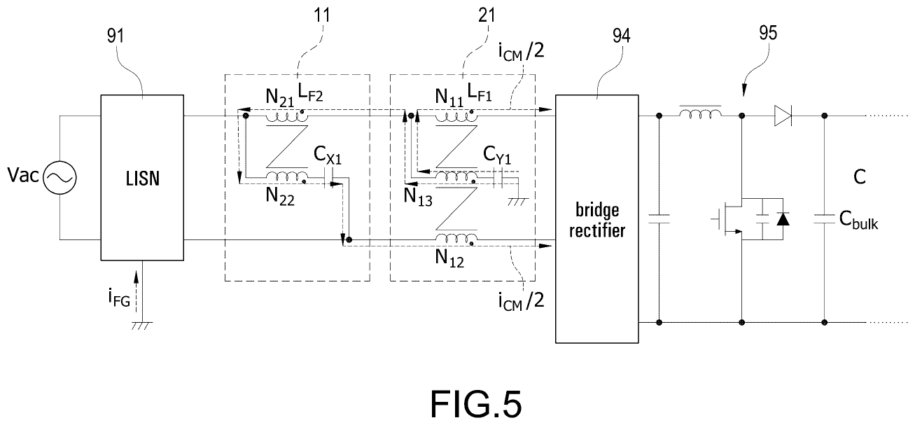

The circuit of the first embodiment shown in FIG. 5 shows the circuit processing of the common-mode noise current i_{CM}/2. It can be clearly seen from FIG. 5 that when the common-mode noise current i_{CM}/2 enters the first winding N₁₁ and the second winding N₁₂ of the common-mode inductor L_{F1} from the live wire and the neutral wire respectively, a synthetic current i_{CM} of the same but opposite direction is generated in the third winding N₁₃. Since the three windings of the common-mode inductor L_{F1} have the same number of turns, the current i_{N11}=current i_{N13}/2, and the mirrored current (=i_{CM}/2) generated by the second winding N₁₂ in the third winding N₁₃ will flow through the first winding N₂₁ and the second winding N₂₂ of the differential-mode inductor L_{F2} and then flow back to the third winding N₁₃. Therefore, it can be observed that the synthetic current i_{CM} is sent out by the noise source on the right and then flows back to the noise source. Therefore, the LISN 91 in FIG. 5 will not detect the common-mode noise currents. Accordingly, through the hybrid noise filter designed in FIG. 2, the differential-mode noise currents and the common-mode noise current can be cancelled.

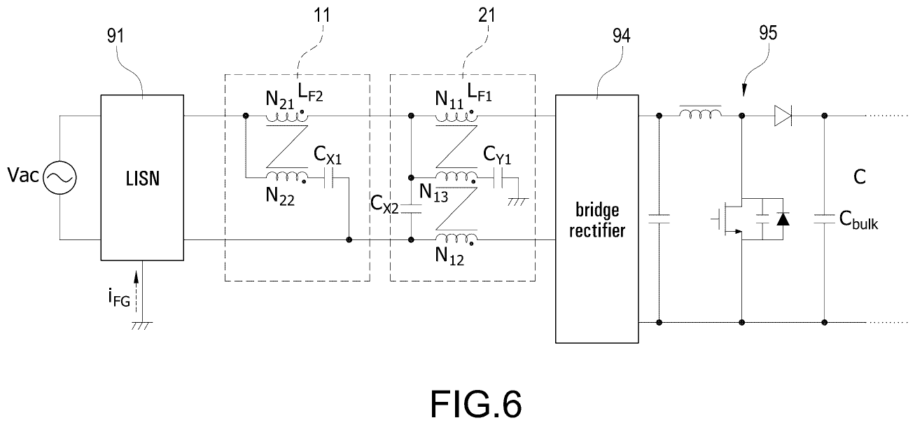

Please refer to FIG. 6, which shows a circuit diagram of the hybrid noise filter according to a second embodiment of the present disclosure. Compared with the first embodiment shown in FIG. 2, the common-mode filter unit 21 of the second embodiment shown in FIG. 6 further includes a second common-mode capacitor C_{X2}. The second common-mode capacitor C_{X2} is connected between the common-mode input side. Specifically, the second common-mode capacitor C_{X2} includes a first terminal and a second terminal. The first terminal of the second common-mode capacitor C_{X2} is connected to the first terminal of the third winding N₁₃, and the second terminal of the second common-mode capacitor C_{X2} is connected to the first terminal of the second winding N₁₂.

FIG. 2 to FIG. 5 are the circuit structures of the first embodiment of the hybrid noise filter and the description of the processing of differential-mode noise currents and common-mode noise currents. The second embodiment of the hybrid noise filter in FIG. 6 may also achieve cancellation of the differential-mode noise currents and the common-mode noise currents. As for the relevant technical content, please refer to the above content and will not be repeated here.

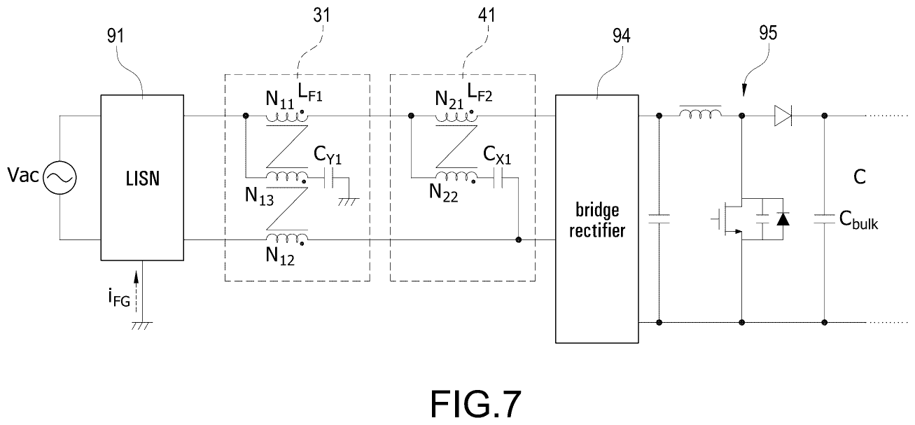

Please refer to FIG. 7, which shows a circuit diagram of the hybrid noise filter according to a third embodiment of the present disclosure. The hybrid noise filter is coupled between an input power source Vac and a power converter. Incidentally, the power converter includes all of or part of a bridge rectifier 94, a voltage conversion circuit 95, a transformer 96, a protection circuit 97, and an output rectifier 98, but the present disclosure is not limited thereto.

As shown in FIG. 7, the hybrid noise filter includes a common-mode filter unit 31 and a differential-mode filter unit 41. The common-mode filter unit 31 includes a common-mode input side (i.e., an input side of the common-mode filter unit 31) and a common-mode output side (i.e., an output side of the common-mode filter unit 31). In particular, the common-mode input side is connected to the input power source Vac, and more specifically, is connected to the input power source Vac through a line impedance stabilization network (LISN) 91. The common-mode filter unit 31 includes a common-mode inductor L_{F1} and a first common-mode capacitor C_{Y1}. The common-mode inductor L_{F1} includes a first winding N₁₁, a second winding N ₁₂, and a third winding N₁₃. The first common-mode capacitor C_{Y1} is connected to the third winding N₁₃ in series and connected to a ground terminal.

The differential-mode filter unit 41 includes a differential-mode input side (i.e., an input side of the differential-mode filter unit 41) and a differential-mode output side (i.e., an output side of the differential-mode filter unit 41), and the differential-mode input side is connected to the common-mode output side and the differential-mode output side is connected to the power converter. The differential-mode filter unit 41 includes a differential-mode inductor L_{F2} and a differential-mode capacitor C_{X1}. The differential-mode inductor L_{F2} includes a first winding N₂₁ and a second winding N₂₂. The differential-mode capacitor C_{X1} is connected to the second winding N₂₂ of the differential-mode inductor L_{F2}.

As shown in FIG. 7, specifically, the first winding N₁₁ of the common-mode inductor L_{F1} includes a first terminal and a second terminal, the second winding N₁₂ of the common-mode inductor L_{F1} includes a first terminal and a second terminal, the third winding N₁₃ of the common-mode inductor L_{F1} includes a first terminal and a second terminal, and the first common-mode capacitor C_{Y1} includes a first terminal and a second terminal. In particular, the first terminal of the first winding N₁₁ is connected to the first terminal of the third winding N₁₃, and the second terminal of the third winding N₁₃ is connected to the first terminal of the first common-mode capacitor C_{Y1}. In particular, the first terminal of the first winding N₁₁ and the first terminal of the second winding N₁₂ form the common-mode input side. In particular, the second terminal of the first winding N₁₁ and the second terminal of the second winding N₁₂ form the common-mode output side.

Furthermore, a polarity of the second terminal of the first winding N₁₁ of the common-mode inductor L_{F1} is the same as a polarity of the second terminal of the second winding N₁₂ of the common-mode inductor L_{F1}, and a polarity of the second terminal of the second winding N₁₂ of t he common-mode inductor L_{F1} is the same as a polarity of the second terminal of the third winding N₁₃ of the common-mode inductor L_{F1}. For example, in this embodiment, the second terminal of the first winding N₁₁, the second terminal of the second winding N₁₂, and the second terminal of the third winding N₁₃ are all dotted polarities; on the contrary, the first termina of the first winding N₁₁, the first terminal of the second winding N₁₂, and the first terminal of the third winding N₁₃ are all non-dotted polarities.

As shown in FIG. 7, specifically, the first winding N₂₁ of the differential-mode inductor L_{F2} includes a first terminal and a second terminal, the second winding N₂₂ of the differential-mode inductor L_{F2} includes a first terminal and a second terminal, and the differential-mode capacitor C_{X1} includes a first terminal and a second terminal. In particular, the first terminal of the first winding N₂₁ is connected to the first terminal of the second winding N₂₂, and the second terminal of the second winding N₂₂ is connected to the first terminal of the differential-mode capacitor C_{X1}. In particular, the first terminal of the first winding N₂₁ and the second terminal of the differential-mode capacitor C_{X1} form the differential-mode input side. In particular, the second terminal of the first winding N₂₁ and the second terminal of the differential-mode capacitor C_{X1} form the differential-mode output side.

Furthermore, a polarity of the second terminal of the first winding N₂₁ of the differential-mode inductor L_{F2} is the same as a polarity of the second terminal of the second winding N₂₂ of the differential-mode inductor L_{F2}. For example, in this embodiment, the second terminal of the first winding N₂₁ and the second terminal of the second winding N₂₂ are both dotted polarities; on the contrary, the first terminal of the first winding N₂₁ and a first terminal of the second winding N₂₂ are all non-dotted polarities.

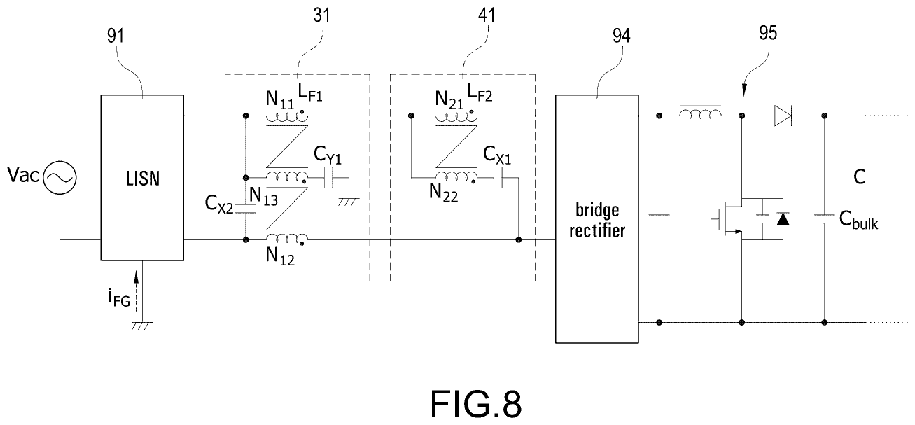

Please refer to FIG. 8, which shows a circuit diagram of the hybrid noise filter according to a fourth embodiment of the present disclosure. The common-mode filter unit 31 of the fourth embodiment shown in FIG. 8 further includes a second common-mode capacitor C_{X2}. The second common-mode capacitor C_{X2} is connected between the common-mode input side. Specifically, the second common-mode capacitor C_{X2} includes a first terminal and a second terminal. The first terminal of the second common-mode capacitor C_{X2} is connected to the first terminal of the third winding N₁₃, and the second terminal of the second common-mode capacitor C_{X2} is connected to the first terminal of the second winding N₁₂.

FIG. 2 to FIG. 5 are the circuit structures of the first embodiment of the hybrid noise filter and the description of the processing of differential-mode noise currents and common-mode noise currents. The third embodiment of the hybrid noise filter in FIG. 7 and the fourth embodiment of the hybrid noise filter in FIG. 8 may also achieve cancellation of the differential-mode noise currents and the common-mode noise currents. As for the relevant technical content, please refer to the above content and will not be repeated here.

Although the present disclosure has been described with reference to the preferred embodiment thereof, it will be understood that the present disclosure is not limited to the details thereof. Various substitutions and modifications have been suggested in the foregoing description, and others will occur to those of ordinary skill in the art. Therefore, all such substitutions and modifications are intended to be embraced within the scope of the present disclosure as defined in the appended claims.

What is claimed is:

1. A hybrid noise filter coupled between an input power source and a power converter, the hybrid noise filter comprising:
a differential-mode filter unit comprising a differential-mode input side and a differential-mode output side, and the differential-mode input side connected to the input power source, the differential-mode filter unit comprising:
a differential-mode inductor comprising a first winding and a second winding, and
a differential-mode capacitor connected to the second winding of the differential-mode inductor in series, and
a common-mode filter unit comprising a common-mode input side and a common-mode output side, and the common-mode input side connected to the differential-mode output side and the common-mode output side connected to the power converter, the common-mode filter unit comprising:
a common-mode inductor comprising a first winding, a second winding, and a third winding, and
a first common-mode capacitor connected to the third winding of the common-mode inductor and connected to a ground terminal.

2. The hybrid noise filter as claimed in claim 1, wherein the first winding of the differential-mode inductor comprises a first terminal and a second terminal, the second winding of the differential-mode inductor comprises a first terminal and a second terminal, and the differential-mode capacitor comprises a first terminal and a second terminal,
wherein the first terminal of the first winding is connected to the first terminal of the second winding, and the second terminal of the second winding is connected to the first terminal of the differential-mode capacitor,
wherein the first terminal of the first winding and the second terminal of the differential-mode capacitor are configured to form the differential-mode input side,
wherein the second terminal of the first winding and the second terminal of the differential-mode capacitor are configured to form the differential-mode output side.

3. The hybrid noise filter as claimed in claim 2, wherein a polarity of the second terminal of the first winding of the differential-mode inductor is the same as a polarity of the second terminal of the second winding of the differential-mode inductor.

4. The hybrid noise filter as claimed in claim 1, wherein the first winding of the common-mode inductor comprises a first terminal and a second terminal, the second winding of the common-mode inductor comprises a first terminal and a second terminal, the third winding of the common-mode inductor comprises a first terminal and a second terminal, and the first common-mode capacitor comprises a first terminal and a second terminal,
wherein the first terminal of the first winding is connected to the first terminal of the third winding, and the second terminal of the third winding is connected to the first terminal of the first common-mode capacitor,
wherein the first terminal of the first winding and the first terminal of the second winding are configured to form the common-mode input side,
wherein the second terminal of the first winding and the second terminal of the second winding are configured to form the common-mode output side.

5. The hybrid noise filter as claimed in claim 4, wherein a polarity of the second terminal of the first winding of the common-mode inductor is the same as a polarity of the second terminal of the second winding of the common-mode inductor, and a polarity of the second terminal of the second winding of the common-mode inductor is the same as a polarity of the second terminal of the third winding of the common-mode inductor.

6. The hybrid noise filter as claimed in claim 1, wherein the common-mode filter unit further comprises:
a second common-mode capacitor connected between the common-mode input side.

7. The hybrid noise filter as claimed in claim 4, wherein the common-mode filter unit further comprises:
a second common-mode capacitor comprising a first terminal and a second terminal,
wherein the first terminal of the second common-mode capacitor is connected to the first terminal of the third winding, and the second terminal of the second common-mode capacitor is connected to the first terminal of the second winding.

8. A hybrid noise filter coupled between an input power source and a power converter, the hybrid noise filter comprising
a common-mode filter unit comprising a common-mode input side and a common-mode output side, and the common-mode input side connected to the input power source, the common-mode filter unit comprising:
a common-mode inductor comprising a first winding, a second winding, and a third winding, and
a first common-mode capacitor connected to the third winding of the common-mode inductor in series and connected to a ground terminal, and
a differential-mode filter unit comprising a differential-mode input side and a differential-mode output side, and the differential-mode input side connected to the common-mode output side and the differential-mode output side connected to the power converter, the differential-mode filter unit comprising:
a differential-mode inductor comprising a first winding and a second winding, and
a differential-mode capacitor connected to the second winding of the differential-mode inductor.

9. The hybrid noise filter as claimed in claim 8, wherein the first winding of the common-mode inductor comprises a first terminal and a second terminal, the second winding of the common-mode inductor comprises a first terminal and a second terminal, and the first common-mode capacitor comprises a first terminal and a second terminal,
wherein the first terminal of the first winding is connected to the first terminal of the third winding, and the second terminal of the third winding is connected to the first terminal of the first common-mode capacitor,
wherein the first terminal of the first winding and the first terminal of the second winding are configured to form the common-mode input side,
wherein the second terminal of the first winding and the second terminal of the second winding are configured to form the common-mode output side.

10. The hybrid noise filter as claimed in claim 9, wherein a polarity of the second terminal of the first winding of the common-mode inductor is the same as a polarity of the second terminal of the second winding of the common-mode inductor, and a polarity of the second terminal of the second winding of the common-mode inductor is the same as a polarity of the second terminal of the third winding of the common-mode inductor.

11. The hybrid noise filter as claimed in claim 8, wherein the first winding of the differential-mode inductor comprises a first terminal and a second terminal, the second winding of the differential-mode inductor comprises a first terminal and a second terminal, and the differential-mode capacitor comprises a first terminal and a second terminal,
wherein the first terminal of the first winding is connected to the first terminal of the second winding, and the second terminal of the second winding is connected to the first terminal of the differential-mode capacitor,
wherein the first terminal of the first winding and the second terminal of the differential-mode capacitor are configured to form the differential-mode input side,
wherein the second terminal of the first winding and the second terminal of the differential-mode capacitor are configured to form the differential-mode output side.

12. The hybrid noise filter as claimed in claim 11, wherein a polarity of the second terminal of the first winding of the differential-mode inductor is the same as a polarity of the second terminal of the second winding of the differential-mode inductor.

13. The hybrid noise filter as claimed in claim 8, wherein the common-mode filter unit further comprises:
a second common-mode capacitor connected between the common-mode input side.

14. The hybrid noise filter as claimed in claim 9, wherein the common-mode filter unit further comprises:
a second common-mode capacitor comprising a first terminal and a second terminal,
wherein the first terminal of the second common-mode capacitor is connected to the first terminal of the third winding, and the second terminal of the second common-mode capacitor is connected to the first terminal of the second winding.
